(19) United States
(12) Patent Application Publication
(10) Pub. No.: US 2010/0326514 A1
(43) Pub. Date: Dec. 30, 2010

(54) SOLAR CELL

(75) Inventor: Toyozo NISHIDA, Takarazuka City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/825,616

(22) Filed: Jun. 29, 2010

(30) Foreign Application Priority Data
Jun. 29, 2009 (JP) 2009-153521

(51) Int. Cl. H01L 31/04

(52) U.S. Cl. 136/256; 136/252

(57) ABSTRACT

A solar cell includes: a photoelectric conversion body having a light receiving surface through which irradiation light may enter to the photoelectric conversion body; a light transmission body provided on the light receiving surface of the photoelectric conversion body, the light transmission body having a light receiving surface; and an electrode provided on the light receiving surface of the photoelectric conversion body, the electrode having a portion extending to and provided on a part of the light receiving surface of the light transmission body.

### CROSS REFERENCE TO RELATED APPLICATIONS

This application claims priority based on 35 USC 119 from prior Japanese Patent Application No. P2009-153521 filed on Jun. 29, 2009, entitled “solar cell”, the entire contents of which are incorporated herein by reference.

### BACKGROUND OF THE INVENTION

1. Field of the Invention

The invention relates to a solar cell including a photoelectric conversion body configured to generate carriers upon being irradiated with light and collector electrodes configured to collect the carriers generated by the photoelectric conversion body.

2. Description of Related Art

Solar cells are expected to be new energy source because they can directly convert clean and inexhaustible sunlight into electricity.

Such solar cells include: a photoelectric conversion body configured to generate carriers in response to being irradiated with light such as sunlight; and collector electrodes configured to collect the carriers generated by the photoelectric conversion body, for example.

Specifically, the photoelectric conversion body includes a light receiving surface to receive the irradiation light, and a rear surface opposite to the light receiving surface. The collector electrodes are provided on the light receiving surface or the rear surface of the photoelectric conversion body. Note that the light receiving surface and the rear surface are collectively called main surfaces of the photoelectric conversion body.

In the case where the collector electrodes are provided on the light receiving surface of the photoelectric conversion body, each of the collector electrodes is generally formed in a thin linear shape in order to effectively collect the carriers while reducing the amount of the irradiation light that is blocked by the collector electrodes.

The thinner the collector electrodes, the higher their electrical resistance. Accordingly, it is desirable that the collector electrodes have low electrical resistance. There is proposed a technique to lower the electrical resistance of the collector electrodes, in which the main surface of the photoelectric conversion body has grooves in which the collector electrodes are implanted (for example, Japanese Patent Application Laid-Open No. S61-005584 and Japanese Patent Application Laid-Open No. S63-276278)

### SUMMARY OF THE INVENTION

In view of the desire to decrease the electrical resistance of the collector electrodes, the collector electrodes are generally made of metal such as Ag, Cu, or the like. Thus, it is difficult to make the collector electrodes from a light transmissive material. Therefore, the collector electrodes provided on the light receiving surface of the photoelectric conversion body block the irradiation light.

Even though it is desirable that the collector electrodes be thin as described above, the width of the collector electrodes depends on the accuracy of the device or method of forming the collector electrodes. Accordingly, there may be a case where decreasing the width of the collector electrodes is not sufficient and decreasing the electrical resistance of the collector electrodes by other means may be required.

An object of an aspect of the invention is to provide a solar cell with low electrical resistance of electrode while reducing the blocking of the irradiation light by the electrode.

An aspect of the invention is a solar cell including: a photoelectric conversion body having a light receiving surface through which the irradiation light may enter to the photoelectric conversion body; a light transmission body provided on the light receiving surface of the photoelectric conversion body, the light transmission body having a light receiving surface; and an electrode provided on the light receiving surface of the photoelectric conversion body, the electrode having a portion extending to and provided on a part of the light receiving surface of the light transmission body.

According to the aspect, the solar cell achieves a decreased electrical resistance of the electrode while reducing the blocking of the irradiation light by the electrode.

In the aspect, a thickness of the light transmission body in a direction substantially orthogonal to the light receiving surface may be equal to or greater than approximately 400 nm.

In the aspect, the refraction index of the light transmission body may be 1.4 to 3.6.

In the aspect, the refraction index of the light transmission body may be 1.6 to 1.8.

In the aspect, the light transmission body may be made of a low-elasticity member.

### BRIEF DESCRIPTION OF THE DRAWINGS

FIG. 1 is a view of the configuration of solar cell module 100 according to the first embodiment.

FIG. 2 is a view of the configuration of solar cell module 100 according to the first embodiment.

FIG. 3 is a view of the configuration of solar cell 10 according to the first embodiment.

FIG. 4 is a view of the configuration of solar cell 10 according to the first embodiment.

FIG. 5 is a view of the configuration of collector electrode 13 and light transmission member 14 on the light receiving surface according to the first embodiment.

FIG. 6 is a view illustrating a method of manufacturing collector electrodes 13 and light transmission members 14 on the light receiving surface of photoelectric conversion body 11 according to the first embodiment.

FIG. 7 is a view illustrating the method of manufacturing collector electrodes 13 and light transmission members 14 on the light receiving surface of photoelectric conversion body 11 according to the first embodiment.

FIG. 8 is a view illustrating the method of manufacturing collector electrodes 13 and light transmission members 14 on the light receiving surface of photoelectric conversion body 11 according to the first embodiment.

FIG. 9 is a view of the configuration of solar cell 10 according to modification 1.

FIG. 10 is a view of the configuration of solar cell 10 according to modification 1.

FIG. 11 is a view of the configuration of collector electrodes 13 and light transmission members 14 on the light receiving surface according to modification 1.

### DETAILED DESCRIPTION OF EMBODIMENTS

Descriptions are provided herein below for embodiments based on the drawings. In the respective drawings referenced herein, the same constituents are designated by the same reference numerals and duplicate explanation concerning the same constituents is omitted. All of the drawings are provided to illustrate the respective examples only.

All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

### Brief of Embodiments

A solar cell according to the following embodiments includes: a photoelectric conversion body configured to generate carriers upon being irradiated with light; and collector electrodes configured to collect the carriers generated by the photoelectric conversion body. The photoelectric conversion body has a light receiving surface through which the irradiation light may be incident to the photoelectric conversion body. Provided on the light receiving surface of the photoelectric conversion body are light transmission bodies having a light transmission property. Collector electrodes are provided on the light receiving surface of the photoelectric conversion body. Each collector electrode extends to a part of the light receiving surface of the light transmission body such that the collector electrode is provided on the light receiving surface of the photoelectric conversion body and the part of the light receiving surface of the light transmission body.

Accordingly, even though reduction of the collector electrode width is limited, that is, even through the collector electrode width is wide, the irradiation light is incident through the light transmission body to the light receiving surface of the photoelectric conversion body. This reduces the blocking of the irradiation light by the collector electrodes, while the wide collector electrode lowers the electrical resistance of the collector electrodes

### First Embodiment

### Configuration of Solar Cell Module

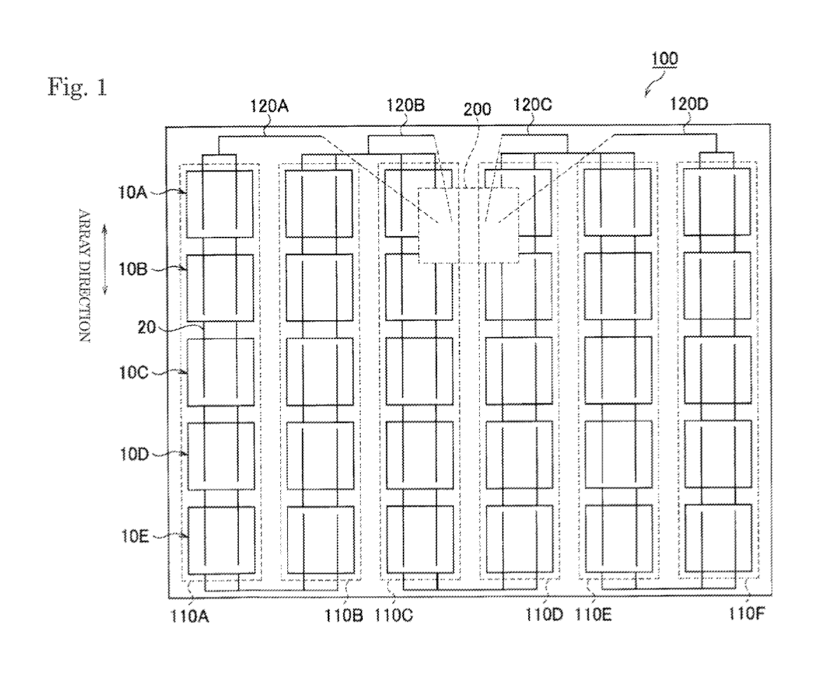

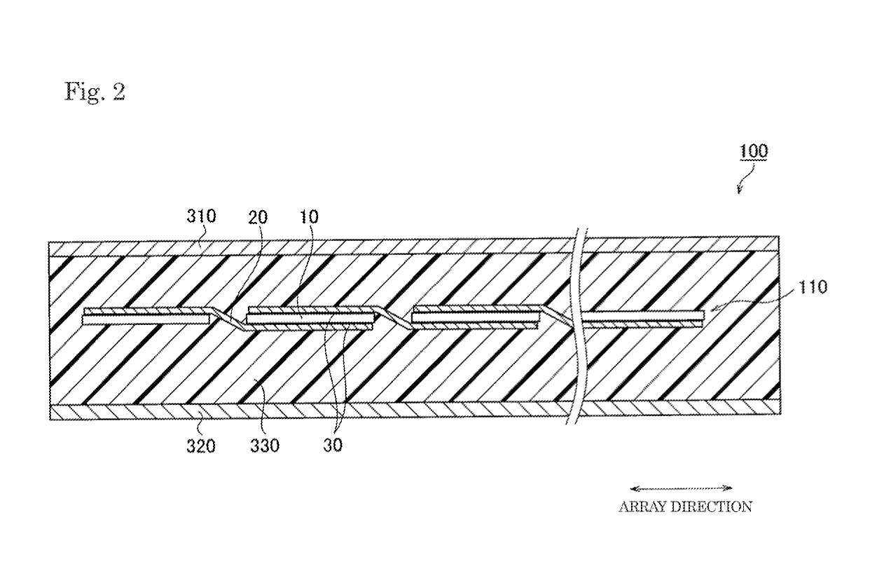

Hereinafter, the configuration of the solar cell module according to the first embodiment is described with reference to the drawings. FIGS. 1 and 2 are views of the configuration of solar cell module 100 according to the first embodiment. Note that FIG. 1 is a plan view of solar cell module 100 as seen from above the light receiving surface that receives the irradiation light and FIG. 2 is a sectional view of solar cell module 100.

First, as shown in FIG. 1, solar cell module 100 includes solar cell strings 110 (solar cell strings 110A to 110F) and terminal box 200.

Each solar cell string 110 is a string of solar cells 10. In each solar cell string 110, plural solar cells 10 are aligned in the array direction (see the arrow in Figs) and are electrically connected to each other by wiring members 20.

For example, solar cell string 110A includes solar cells 10A to 10E. Solar cells 10A to 10E are electrically connected to each other by wiring members 20.

Terminal box 200 is provided on the side of the rear surface opposite to the light receiving surface which receives the irradiation light. Lead wires 120 (120A to 120D), which are connected with wiring members 20, are connected to terminal box 200. Terminal box 200 outputs, via an unillustrated output cable, the electric current that is collected from solar cells 10 via wiring members 20 and lead wires 120.

Second, as show in FIG. 2, solar cell module 100 includes light receiving side protecting member 310 (hereinafter referred to as front cover 310), rear side protecting member 320 (hereinafter referred to as rear cover 320), and sealant 330. Solar cell strings 110, which are described above, are sealed between front cover 310 and rear cover 320 with sealant 330.

Front cover 310 is provided on the sides of the light receiving surfaces of solar cells 10 and protects the light receiving surfaces of solar cells 10. Front cover 310 is made of, for example, a light-transmissive and water-shielding member such as glass, plastic, or the like.

Rear cover 320 is provided on the rear side of solar cells 10 and protects the rear surfaces of solar cells 10. Rear cover 320 is made of, for example, a resin film such as PET (Polyethylene Terephthalate) or a laminate film in which an A1 foil is sandwiched between resin films.

Sealant 330 is filled between front cover 310 and rear cover 320. Sealant 330 is made of a light transmissive material. Sealant 330 is made of, for example, a resin such as EVA, EEA, PVB, silicon, urethane, acrylic, or epoxy.

Note that wiring members 20 are bonded to the surface of solar cell 10 by using adhesive agent 30, which may be solder, conductive adhesive resin, or the like.

Here, routing of wiring members 20 between two adjacent solar cells 10 is described as an example of wiring among plural solar cells 10. Of the two adjacent solar cells 10, one is referred to as first solar cell 10 and the other is referred to as second solar cell 10, in order to make the following description clear. Specifically, wiring member 20 extends between and electrically connects the light receiving surface of the first solar cell 10 and the rear surface of second solar cell 10.

(Configuration of Solar Cell)

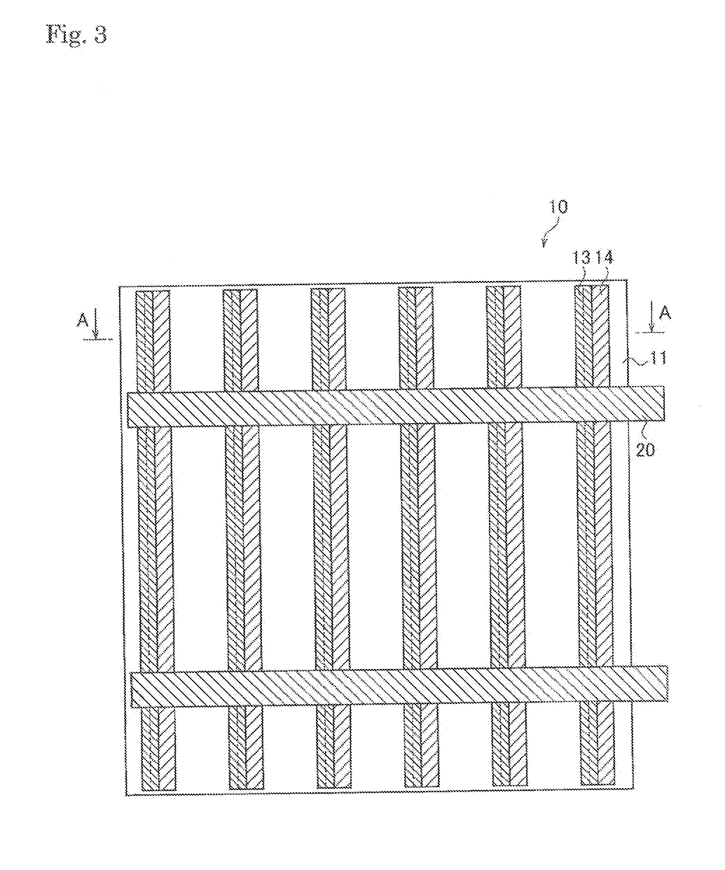

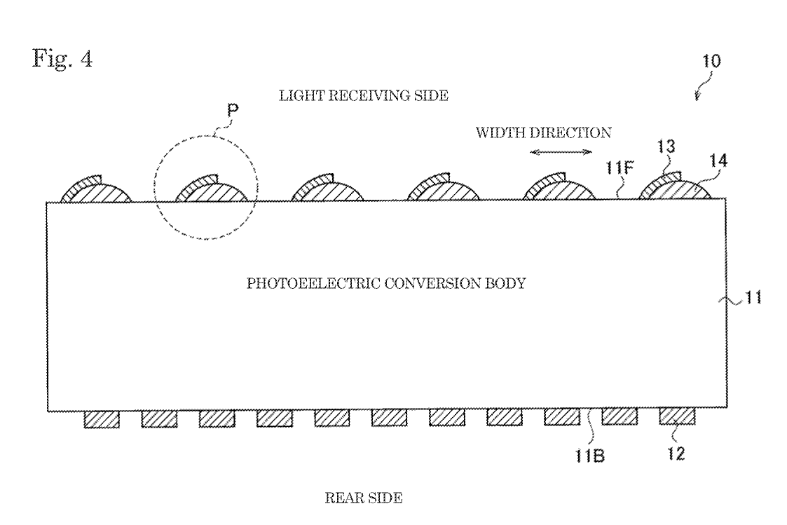

Hereinafter, the configuration of the solar cell according to the first embodiment is described with reference to the drawings. FIGS. 3 and 4 are views of the configuration of solar cell 10 according to the first embodiment. Note that FIG. 3 is a plan view of solar cell 10 as seen from above the light receiving surface and FIG. 4 is a sectional view of solar cell 10 along the A-A line in FIG. 3.

As shown in FIGS. 3 and 4, solar cell 10 includes photoelectric conversion body 11, rear side collector electrodes 12 (hereinafter referred to as rear collector electrodes 12, light receiving side collector electrodes 13 (hereinafter referred to as front collector electrodes 13), and light transmission members 14.

Photoelectric conversion body 11 is configured to generate carriers in response to irradiation with light. The carriers are electron-hole pairs. Photoelectric conversion body 11 has light receiving surface 11F (which may be referred to as a front surface) to receive the irradiation light and rear surface 11B opposite to light receiving surface 11F.

Photoelectric conversion body 11 has therein, for example, a n-type region, a p-type region, and a semiconductor junction at the interface between the n-type region and the p-type region. With this structure, the semiconductor junction at the interface between the n-type region and the p-type region separates the carriers into the holes and the electrons.

Photoelectric conversion body 11 may be a semiconductor substrate formed of a crystalline semiconductor such as single crystalline silicon, polycrystalline silicon, or the like. Photoelectric conversion body 11 may be a semiconductor substrate formed of a compound semiconductor such as GaAs, InP, or the like.

Photoelectric conversion body 11 may have such a structure (HIT structure) that intrinsic amorphous silicon is provided between a single crystalline silicon substrate and an amorphous silicon layer. Such HIT structure improves the properties of the hetero-interface.

Rear collector electrodes 12 are electrodes to collect the carriers (the holes or the electrons). Each rear collector electrode 12 extends in a liner shape and is provided on the rear surface 11B of photoelectric conversion body 11. Rear collector electrodes 12 are disposed with a predetermined distance therebetween. Rear collector electrodes 12 are made of, for example, a low electrical resistance metal such as Ag, Cu, or the like. Rear collector electrodes 12 are preferably formed on substantially the entire region of rear surface 11B of photoelectric conversion body 11.

Front collector electrodes 13 are electrodes to collect the carriers (the electrons or the holes). Each front collector electrode 13 extends in a liner shape and is provided on light receiving surface 11F of photoelectric conversion body 11. Front collector electrodes 13 are disposed with a predetermined distance therebetween. Front collector electrodes 13 are made of, for example, a low electrical resistance metal such as Ag, Cu, or the like. Front collector electrodes 13 are preferably formed on substantially the entire region of light receiving surface 11F of photoelectric conversion body 11.

In the first embodiment, each front collector electrode 13 is provided on light receiving surface 11F of photoelectric conversion body 11 and on a part of the light receiving surface of light transmission member 14 such that front collector electrode 13 extends from light receiving surface 11F of photoelectric conversion body 11 to the part of the light receiving surface of light transmission members 14 (see FIG. 4). More specifically, one side of front collector electrode 13 (almost all the part of front collector electrode 13 in this embodiment) in the width direction of front collector electrode 13 is provided on the part of the light receiving surface of light transmission members 14.

Note that the light receiving surface of light transmission member 14 has an exposed area (an uncovered area) which is not covered with front collector electrode 13. With this configuration, the irradiation light enters from the exposed area of the light receiving surface of light transmission member 14 to light receiving surface 11F of photoelectric conversion body 11.

The predetermined distance between adjacent front collector electrodes 13 is preferably wider than the predetermined distance between adjacent rear collector electrodes 12. In such a structure, the number of front collector electrodes 13 is preferably less than the number of rear collector electrodes 12. The wider the distance between front collector electrodes 13, the less the amount of irradiation light that is blocked by front collector electrodes 13. The narrower the distance between rear collector electrodes 12, the higher the collection efficiency of the carriers by rear collector electrodes 12.

In the first embodiment, wiring member 20 is electrically connected to front collector electrodes 13 of first solar cell 10 and electrically connected to rear collector electrodes 12 of second solar cell 10, which is adjacent to first solar cell 10.

Just beneath wiring member 20, there may be a gathering electrode to gather the carriers that are collected by front collector electrodes 13. Such gathering electrode functions as an electrode to electrically connect wiring member 20 to front collector electrodes 13. Similarly, just beneath wiring member 20, there may be a gathering electrode to gather the carriers that are collected by rear collector electrodes 12. Such gathering electrode functions as an electrode to electrically connect wiring member 20 to rear collector electrodes 12.

Light transmission members 14 are formed of light transmissive material. Each light transmission member 14 extends in a liner shape and is provided on light receiving surface 11F of photoelectric conversion body 11. Light transmission members 14 are disposed with a predetermined distance therebetween. In other words, each light transmission member 14 is provided along each front collector electrode 13.

In the first embodiment, at least a part of light transmission member 14 is provided between front collector electrode 13 and light receiving surface 11F of photoelectric conversion body 11 (see FIG. 4).

The refraction index of light transmission member 14 is preferably higher than that of sealant 330 and preferably lower than that of photoelectric conversion body 11.

For example, light transmission member 14 is preferably formed of a material whose refraction index is 1.4 to 3.6, and further preferably formed of a material whose refraction index is 1.6 to 1.8.

The following material may be used for the material of light transmission member 14.

(A) The following inorganic materials (A1 to A3) can be used for the material of light transmission member 14.
(A1) Light transmissive material composed of at least one material selected from the metal oxide group including indium oxide, lead oxide, zinc oxide, titanium oxide, tantalum oxide, silicon oxide, aluminum oxide, zirconium oxide, and the like
(A2) Light transmissive material (A1) further comprising at least one element selected from the group consisting of rare-earth element, alkali metal element, alkali earth metal element, gallium, fluorine, and the like
(A3) Diamond

(B) The following organic materials (B1 to B5) can be used for the material of light transmission member 14.
(B1) Methacrylate resin
(B2) Acrylic resin
(B3) Polycarbonate resin
(B4) Polystyrene resin
(B5) Polyester resin

For example, general-purpose polystyrene resin has the refraction index of 1.59 to 1.60. AS resin (Acrylonitrile-styrene copolymer) has the refraction index of 1.56 to 1.58. MS resin (Styrene-methylmethacrylate copolymer) has the refraction index of 1.56 to 1.58. Acrylic resin has the refraction index of 1.49 to 1.50. Polycarbonate resin has the refraction index of 1.58 to 1.59. Hard vinyl chloride resin has the refraction index of 1.52 to 1.54. Polymethylmethacrylate has the refraction index of about 1.50.

(C) Hybrid material, which is an organic material containing particles of an inorganic material, can be used for the material of light transmission member 14. Note that the materials that are listed in item (A) or carbon nanostructures can be used as the inorganic material and the materials that are listed in item (B) can be used as the organic material.

(D) It is preferable to use a low-elasticity member as the material of light transmission member 14. The following materials (D1 to D6) can be used as the material of the low-elasticity member.
(D1) Epoxy resin (polyglycidyl ether type epoxy resin)
(D2) Acrylic resin
(D3) Fluorine resin
(D4) Styrene elastomer
(D5) Polypropylene
(D6) Polyimide silicon

(Configuration of Light Transmission Body and Collector Electrode)

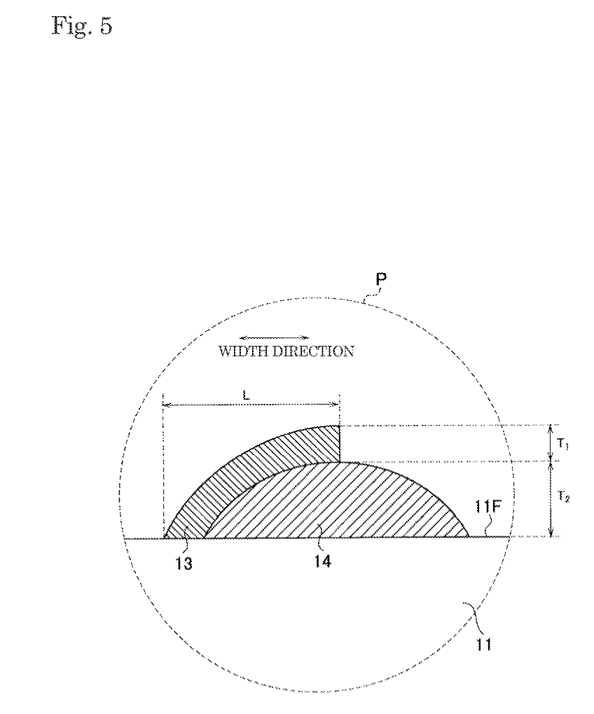

The configuration of the light transmission body and the collector electrode is described below with reference to the drawings. FIG. 5 is a view of the configuration of front collector electrode 13 and light transmission member 14 according to the first embodiment.

As shown in FIG. 5, front collector electrode 13 is provided on light receiving surface 11F of photoelectric conversion body 11 and on the part of the light receiving surface of light transmission member 14 such that front collector electrode 13 extends from light receiving surface 11F of photoelectric conversion body 11 to the part of the light receiving surface of light transmission members 14. More specifically, one side of front collector electrode 13 (almost all the part of front collector electrode 13 in this embodiment) in the width direction of front collector electrode 13 is provided on the part of the light receiving surface of light transmission members 14. At least a part of light transmission member 14 is provided between front collector electrode 13 and light receiving surface 11F of photoelectric conversion body 11.

Thickness T1 of front collector electrodes 13 is substantially 10 μnm to 100 nm in a direction substantially orthogonal to light receiving surface 11F of photoelectric conversion body 11. In the width direction of front collector electrode 13, length L of the front surface of front collector electrode 13 is substantially 40 μm to 100 μm. Note that length L of the front surface of front collector electrode 13 depends on the accuracy of the method or the device for forming front collector electrode 13.

Thickness T2 of light transmission member 14 is preferably equal to or greater than about 400 nm in the direction substantially orthogonal to light receiving surface 11F of photoelectric conversion body 11. Thickness T2 of light transmission member 14 is further preferably equal to or greater than about 800 nm. Thickness T2 of light transmission member 14 is further preferably equal to or greater than the wave length (for example, 2 μm) of the irradiation light incident on light receiving surface 11F of photoelectric conversion body 11.

Thickness T2 of light transmission member 14 is preferably equal to or less than about 100 μm in the direction substantially orthogonal to light receiving surface 11F of photoelectric conversion body 11.

(Method for Manufacturing Light Transmission Body and Collector Electrode)

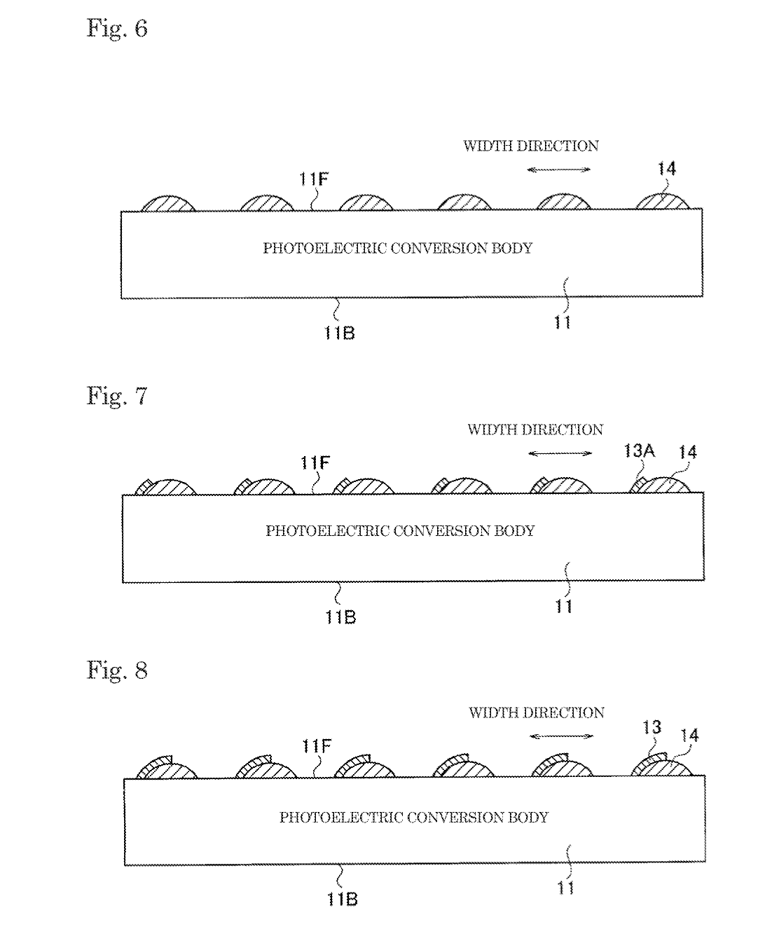

Hereinafter, the method for manufacturing the light transmission body and the collector electrode according to the first embodiment is described with reference to the drawings. FIGS. 6 to 8 are views illustrating the manufacturing method of front collector electrode 13 and light transmission member 14 according to the first embodiment.

First, as shown in FIG. 6, light transmission members 14 are formed on light receiving surface 11F of photoelectric conversion body 11. For example, light transmission members 14 are formed by using a UV photolithography technique. Note that light transmission members 14 are disposed with the predetermined distance therebetween, as described above.

Second, as shown in FIG. 7, plural lines of collector electrode material 13A are formed on light receiving surface 11F of photoelectric conversion body 11. The plural lines of collector electrode material 13A may be formed by using a non-electrolytic plating technique.

Collector electrode material 13A is a material for front collector electrode 13. Accordingly, collector electrode material 13A is the same material as that of front collector electrode 13.

Each line of collector electrode material 13A extends along each light transmission member 14. More specifically, one side of each collector electrode material 13A in the width direction of collector electrode material 13A is formed on a part of the light receiving surface of light transmission member 14.

Third, as shown in FIG. 8, front collector electrodes 13 are formed. For example, each front collector electrode 13 may be formed by growing each collector electrode material 13A by an electrolytic plating technique.

As described above, since each collector electrode material 13A is along each light transmission member 14, each front collector electrode 13 is formed on the light receiving surface of photoelectric conversion body 111 and on a part of the light receiving surface of each light transmission member 14.

(Functions and Effects)

According to the first embodiment, each front collector electrode 13 is provided on light receiving surface 11F of photoelectric conversion body 11 and the part of the light receiving surface of light transmission member 14 such that front collector electrode 13 extends from light receiving surface 11F of photoelectric conversion body 11 to the part of the light receiving surface of light transmission member 14. Accordingly, even if front collector electrode 13 is wide (that is, even if reduction of the width of front collector electrode 13 is limited), the irradiation light enters light receiving surface 11F of photoelectric conversion body 11 through light transmission members 14, and this reduces the blocking of the irradiation light by front collector electrode 13, while decreasing the electrical resistance of front collector electrode 13 due to the wide width of front collector electrode 13.

Specifically, one side of front collector electrode 13 in the width direction of front collector electrodes 13 is provided on the part of the light receiving surface of light transmission members 14. Accordingly, at the one side of front collector electrodes 13, the amount of the light that is blocked by front collector electrode 13 is reduced.

More specifically, the light receiving surface of light transmission members 14 has the exposed area (uncovered area), which is an area that is uncovered with front collector electrode 13. Accordingly, the irradiation light enters light receiving surface 11F of photoelectric conversion body 11 from the exposed area of the light receiving surface of light transmission members 14. This reduces the blocking of the irradiation light by front collector electrode 13.

In the first embodiment, light transmission member 14 is preferably formed of a material whose refraction index is 1.4 to 3.6. This increases the amount of the irradiation light that enters light receiving surface 11F of photoelectric conversion body 11 through light transmission members 14.

In the first embodiment, light transmission member 14 is further preferably formed of a material whose refraction index is 1.6 to 1.8. This further increases the amount of the irradiation light that enters light receiving surface 11F of photoelectric conversion body 11 through light transmission members 14.

In the first embodiment, light transmission member 14 is preferably formed of a low-elasticity member. This improves the interface adherence between front collector electrodes 13 and wiring member 20 in a state where wiring member 20 is adhered to front collector electrodes 13.

In the first embodiment, thickness T2 of light transmission member 14 is preferably equal or greater than approximately 400 nm. This reduces the amount of light that is blocked by front collector electrodes 13, that is, increases the amount of light that enters light receiving surface 11F of photoelectric conversion body 11 through light transmission members 14.

In the first embodiment, thickness T2 of light transmission member 14 is preferably equal to or greater than approximately 800 nm. This further reduces the amount of light that is blocked by front collector electrodes 13, that is, further increases the amount of light that enters light receiving surface 11F of photoelectric conversion body 11 through light transmission members 14.

In the first embodiment, thickness T2 of light transmission member 14 is further preferably equal to or more than the wave length (for example, 2 μm) of the irradiation light incident on light receiving surface 11F of photoelectric conversion body 11. This increases the amount of the irradiation light that enters light receiving surface 11F of photoelectric conversion body 11 through light transmission members 14.

In the first embodiment, thickness T2 of light transmission member 14 is preferably equal to or less than approximately 100 μm. This prevents or reduces flaking of light transmission member 14 from photoelectric conversion body 11.

[Modification 1]

Hereinafter, modification 1 of the first embodiment is described with reference to the drawings. Here, differences from the first embodiment are mainly described.

In the first embodiment, the one widthwise side of front collector electrode 13 is provided on the light receiving surface of light transmission members 14 and the other widthwise side of front collector electrode 13 is provided on photoelectric conversion body 11. On the other hand, in modification 1, one widthwise side of front collector electrode 13 is provided on a part of the light receiving surface of one of two adjacent light transmission members 14 and the other widthwise side of front collector electrode 13 is provided on a part of the light receiving surface of the other of the two adjacent light transmission members. Note that in modification 1, light transmission members 14 covers almost the entire area of light receiving surface 11F of photoelectric conversion body 11.

(Configuration of Solar Cell)

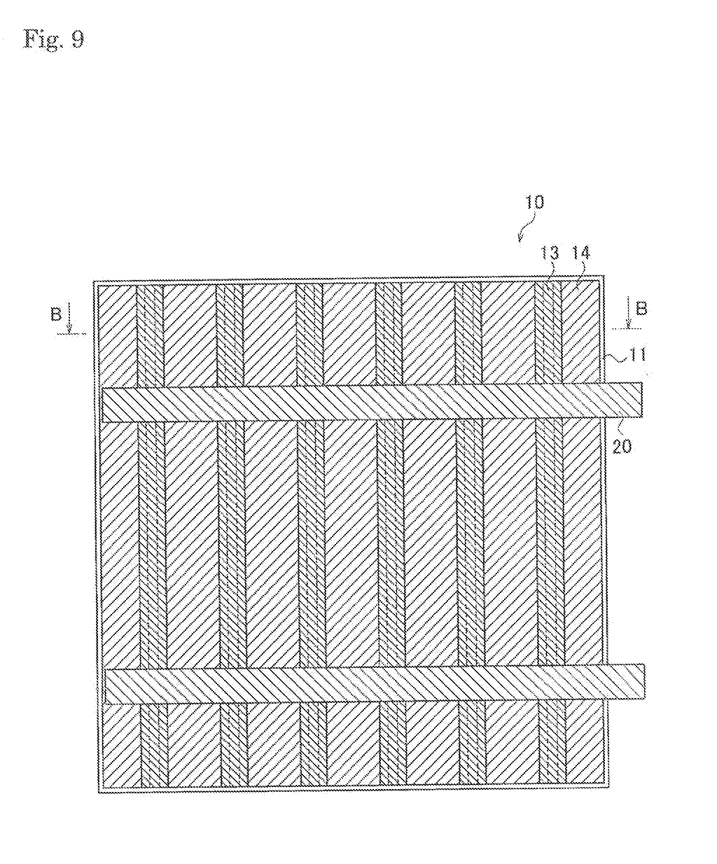

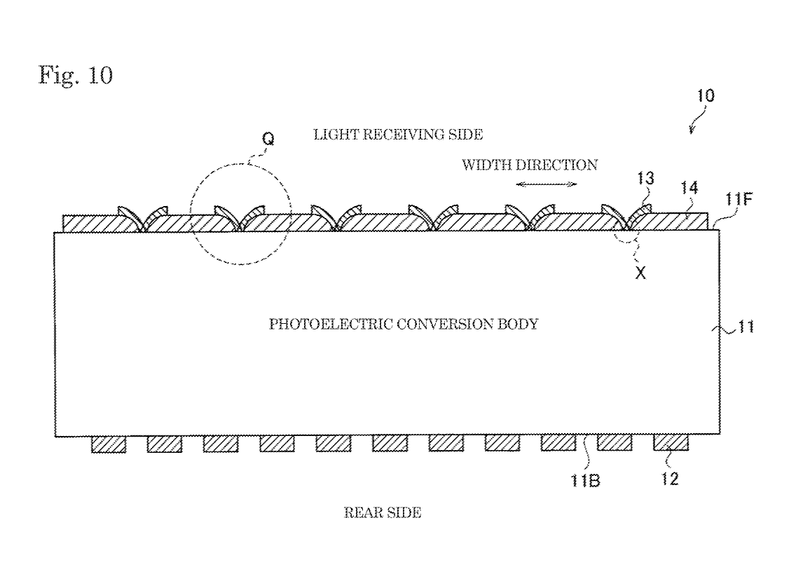

The configuration of the solar cell according to modification 1 is described below with reference to the drawings. FIGS. 9 and 10 are views of the configuration of solar cell 10 according to modification 1. FIG. 9 is a view of solar cell 10 as seen from above the light receiving surface of solar cell 10. FIG. 10 is a sectional view of solar cell 10 along B-B line in FIG. 9. Note that in FIGS. 9 and 10, the same or similar constituents as in FIGS. 3 and 4 are designated by the same numeral numbers as in FIGS. 3 and 4.

As shown in FIGS. 9 and 10, solar cell 10 includes photoelectric conversion body 11, rear collector electrodes 12, front collector electrodes 13, and light transmission members 14.

Photoelectric conversion body 11 and rear collector electrodes 12 have the same configuration as those of the first embodiment, and thus the explanation for them is omitted.

Like the first embodiment, each of front collector electrodes 13 is an electrode to collect the carriers (holes or electrons). Each front collector electrode 13 extends in a liner shape and is provided on light receiving surface 11F of photoelectric conversion body 11.

In modification 1, each front collector electrode 13 extends from light receiving surface 11F of photoelectric conversion body 11 to a part of the light receiving surface of either of two adjacent light transmission members 14 (see FIG. 10). Specifically, one widthwise side of front collector electrode 13 is provided on a part of the light receiving surface of one of two adjacent light transmission members 14 and the other widthwise side of front collector electrode 13 is provided on a part of the light receiving surface of the other of the two adjacent light transmission members 14.

Like the first embodiment, light transmission members 14 are made of light transmissive material. Light transmission members 14 are provided on light receiving surface 11F of photoelectric conversion body 11.

In modification 1, light transmission members 14 cover almost the entire area of light receiving surface 11F of photoelectric conversion body 11. Specifically, except for areas X where front collector electrodes 13 contact to light receiving surface 11F of photoelectric conversion body 11, light transmission members 14 cover substantially the entire area of light receiving surface 11F of photoelectric conversion body 11.

(Light Transmission Bodies and Collector Electrode)

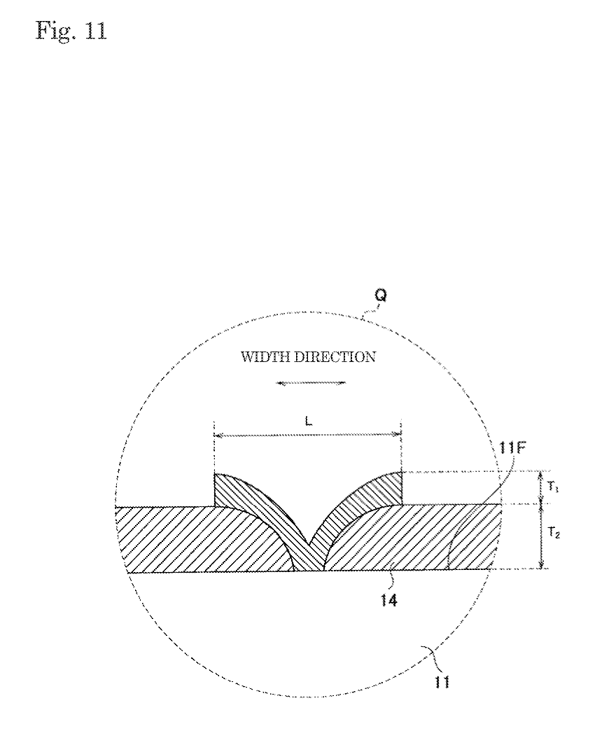

A relationship between the light transmission bodies and the collector electrode according to modification 1 is described below with reference to the drawings. FIG. 11 is a view illustrating the relationship between front collector electrode 13 and light transmission members 14.

As shown in FIG. 11, each front collector electrode 13 extends from light receiving surface 11F of photoelectric conversion body 11 to a part of the light receiving surface of either of two adjacent light transmission members 14. Specifically, one widthwise side of front collector electrode 13 is provided on a part of the light receiving surface of one of two adjacent light transmission members 14 and the other widthwise side of front collector electrode 13 is provided on a part of the light receiving surface of the other of the two adjacent light transmission members 14. At least apart of light transmission member 14 is provided between light receiving surface 11F of photoelectric conversion body 11 and front collector electrode 13.

Here, thickness T1 of front collector electrode 13 is approximately 10 μnm to 100 nm in a direction substantially orthogonal to light receiving surface 11F of photoelectric conversion body 11. In a width direction of front collector electrode 13, length L of each front collector electrode 13 is approximately 40 μm to 100 μm. Note that length L of front collector electrode 13 depends on the accuracy of the device or method for forming front collector electrodes 13.

It is preferable that thickness T2 of light transmission members 14 is equal to or greater than approximately 400 nm in the direction substantially orthogonal to light receiving surface 11F of photoelectric conversion body 11. It is further preferable that thickness Ts of light transmission members 14 is equal to or greater than approximately 800 nm. It is further preferable that thickness T2 of light transmission member 14 is equal to or greater than the wave length (for example, 2 μm) of the irradiation light that is incident on light receiving surface 11F of photoelectric conversion body 11.

On the other hand, it is preferable that thickness T2 of light transmission members 14 is equal to or less than approximately 100 μm in the direction substantially orthogonal to light receiving surface 11F of photoelectric conversion body 11.

(Functions and Effects)

According to modification 1, either widthwise side of front collector electrode 13 is provided on the part of the light receiving surface of either of two adjacent light transmission members 14. Accordingly, at either widthwise side of front collector electrode 13, the amount of the irradiation light that is blocked by front collector electrode 13 is reduced. That is to say, modification 1 further reduces the blocking of the irradiation light by front collector electrode 13.

### Other Embodiment(s)

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

For example, although light transmission members 14 are provided on light receiving surface 11F of photoelectric conversion body 11 and each front collector electrode 13 extends to a part of the light receiving surface of each or either of adjacent light transmission members 14 in the above-described embodiments, embodiments according to the invention are not limited to the above-described embodiments. Specifically, an embodiment may have such a structure that light transmission members 14 are provided on rear surface 11B of photoelectric conversion body 11 and each rear collector electrode 12 extends to a part of the light receiving surface of light transmission member 14. In the case where the irradiation light is reflected by rear cover 320, it is preferable that rear collector electrode 12 extends to a part of the light receiving surface of light transmission member 14.

What is claimed is:

1. A solar cell comprising:
a photoelectric conversion body having a light receiving surface through which irradiation light may enter to the photoelectric conversion body;
a light transmission body provided on the light receiving surface of the photoelectric conversion body, the light transmission body having a light receiving surface; and
an electrode provided on the light receiving surface of the photoelectric conversion body, the electrode having a portion extending to and provided on apart of the light receiving surface of the light transmission body.

2. The solar cell of claim 1, wherein
at least a portion of the light transmission body is provided between the electrode and the light receiving surface of the photoelectric conversion body.

3. The solar cell of claim 1, wherein
the light receiving surface of the light transmission body has an exposed area which is not covered with the electrode.

4. The solar cell of claim 1, wherein
a thickness of the light transmission body in a direction substantially orthogonal to the light receiving surface is equal to or greater than approximately 400 nm.

5. The solar cell of claim 1, wherein
the refraction index of the light transmission body is 1.4 to 3.6.

6. The solar cell of claim 1, wherein
the refraction index of the light transmission body is 1.6 to 1.8.

7. The solar cell of claim 1, wherein
the light transmission body is made of a low-elasticity member.

8. The solar cell of claim 1, wherein
the light transmission body includes resin material.

9. The solar cell of claim 1, wherein
the light transmission body projects from the light receiving surface of the photoelectric conversion body.

10. The solar cell of claim 4, wherein
the light receiving surface of the photoelectric conversion body is a substantially flat.

11. The solar cell of claim 9, wherein
the light receiving surface of the light transmission body has a curved shape in the cross section along the width direction of the collector electrode.

12. The solar cell of claim 9, wherein
the light receiving surface of the light transmission body has a substantially circular arc shape in the cross section along the width direction of the collector electrode.

13. The solar cell of claim 1, wherein
the electrode has an inclined portion which is inclined with respect to the light receiving surface of the photoelectric conversion body.

14. The solar cell of claim 13, wherein
the inclined portion extends in a linear shape.

15. The solar cell of claim 13, wherein
the inclined portion extends in a circular arc fashion.

16. The solar cell of claim 1, wherein
the electrode has a substantially V shape in the cross section along a width direction of the collector electrode.

17. The solar cell of claim 1, wherein
a first contact area between the electrode and the light receiving surface of the light transmission body is larger than a second contact area between the electrode and the light receiving surface of the photoelectric conversion body.

18. The solar cell of claim 1, wherein
the electrode comprises plural parallel collector electrodes provided on the light receiving surface of the photoelectric conversion body with a predetermined distance between the parallel collector electrodes,
the light transmission body comprises plural light transmission bodies respectively provided along the parallel collector electrodes, and
the collector electrodes each has the portion extending to and provided on the part of the light receiving surface of one or more of the plural light transmission bodies.

19. The solar cell of claim 18, wherein,
each parallel collector electrode has a longitudinal direction and a width direction,
at least one widthwise side of each parallel collector electrode extends to and is provided on the part of the light receiving surface of each plural light transmission body.

20. The solar cell of claim 19, wherein
one widthwise side of each parallel collector electrode extends to and on the part of the light receiving surface of one of adjacent two of the plural light transmission bodies, and
the other widthwise side of each parallel collector electrode extends to and on the part of the light receiving surface of the other of the adjacent two of the plural light transmission bodies.
